(19) United States
(12) Patent Application Publication
(10) Pub. No.: US 2026/0257254 A1
(43) Pub. Date: Sep. 3, 2026

(54) DEVICE FOR CLEANING POT-SHAPED HOLLOW BODIES, IN PARTICULAR OF TRANSPORT CONTAINERS FOR SEMICONDUCTOR WAFERS OR FOR LITHOGRAPHY MASKS

(71) Applicant: GSEC GERMAN SEMICONDUCTOR EQUIPMENT COMPANY GMBH, Radolfzell am Bodensee (DE)

(72) Inventor: Frank Schienle, Freiburg (DE)

(21) Appl. No.: 18/873,347

(22) PCT Filed: Jun. 15, 2023
(86) PCT No.: PCT/EP2023/066087

§ 371 Date: Dec. 10, 2024

(30) Foreign Application Priority Data
Jun. 29, 2022 (DE) 10 2022 116 177.3

(51) Int. Cl. B08B 9/093; B08B 9/08

(52) U.S. Cl. CPC B08B 9/093; B08B 9/0826

(57) ABSTRACT

The present invention relates to a device (10) for cleaning pot-shaped hollow bodies (12), in particular transport containers (30) for semiconductor wafers or for lithography masks, wherein the hollow body (12) comprises a base wall (32) and one or more side walls (34) that form an inner hollow body surface (33) and an opening (36) that is disposed opposite the base wall (32) and that is surrounded by a marginal surface (38) of the side wall (34). The device (10) comprises a support wall (20) on which the marginal surface (389 of the hollow body (12) can be placed, a cleaning device (40) by which a first cleaning fluid for cleaning the inner hollow body surface (33) can be dispensed when the hollow body (12) is connected to the support wall (20) and a feed device (37) that is arranged in the support wall (20) or is fastened to the support wall(20) and by which a flushing fluid can be guided to the marginal surface (38), with the feed device (37) comprising a movable element (39) that is movable toward the marginal surface (38) by the flushing fluid.

### BACKGROUND

### Field of the Invention

Embodiments provided herein relate to a device for cleaning pot-shaped hollow bodies, in particular transport containers for semiconductor wafers or for lithography masks.

### Description of the Related Art

The manufacture of highly integrated electronic circuits and other sensitive semiconductor components takes place today in factories in which so-called semiconductor wafers run through a large number of processing steps. A large part of these processing steps takes place in clean rooms that are kept free of contaminants, in particular free of particles, with a high effort. Such a complex processing is necessary since particles that come into contact with the semiconductor material of the semiconductor wafers can in particular influence the material properties of the semiconductor wafers such that a total production batch becomes defective and unusable and has to be scrapped.

Since the keeping clean is becoming more and more important as the integration density of the semiconductor circuits and the effort to keep clean increase exponentially as the size of the clean rooms increases, the semiconductor wafers are not transported from one processing station to the next in an “open” state. Special transport containers (so-called FOUPs, front opening unified pods) are used instead. They are understood as box-shaped transport containers into which a large number of semiconductor wafers is inserted and that typically consist of an injection molded plastic. The FOUPs are typically closed by a removable cover. Without the cover the FOUPs have a pot-shaped basic shape with a rectangular base surface and an inner surface and an outer surface that are separated from one another by a marginal surface. When the FOUPs are closed by their lids, the inserted semiconductor wafers can be transported from one clean room to another clean room protected from the environment. When the FOUPs have reached a processing station, they are opened, the semiconductor wafers are removed, and are processed accordingly. After processing has taken place, the semiconductor wafers are transported back into the FOUPs and are then conveyed to the next processing station.

Due to the high production downtimes on contaminations of the semiconductor wafers, it is necessary to clean the FOUPs from time to time. The FOUPs are in particular contaminated by the wear debris of the semiconductor wafers on the introduction into and the removal from the FOUPs.

The same applies accordingly to transport containers for lithography masks and in particular for EUV lithography masks (“extreme ultraviolet radiation”). The lithography masks are used to manufacture very small integrated circuits. The lithography masks, like the semiconductors, also have to be transported, with a similar situation arising. When FOUPs are spoken of in the following, the statements in this respect apply equally to transport containers for lithography masks and in particular for EUV lithography masks.

Devices for cleaning FOUPs are known, for example, from US 2002/0046760 A1,US 2003/0102015 A1, U.S. Pat. No. 8,591.664 B2, JP 2005 109523A, WO 2005/001888 A2 and EP 1 899 084 B1.

With such cleaning devices, the FOUPs are cleaned both on both their inner surfaces and their outer surfaces. The FOUPs are typically contaminated much more strongly on their outer surfaces than on their inner surfaces. As a result, the cleaning fluid accumulates both particles that originate from the outer surfaces and particles that originate from the inner surfaces during the cleaning procedure. The particles can therefore be transported from the outer surfaces to the inner surfaces. A satisfactory cleaning result is, however, only reached when the number of particles has fallen below a certain value. Due to the particles originating from the outer surface, the cleaning procedure has to be carried out for a correspondingly long time period to be able to remove a sufficient portion of the particles. This is disadvantage to the extent that, on the one hand, the amount of the required cleaning fluid is comparatively high and, on the other hand, the FOUPs cannot be used to transport the semiconductor wafers during the cleaning process. The production of the semiconductor wafers is hereby made more expensive. There is additionally the fact that a cleaning of the outer surface only contributes to the reduction of defective semiconductor wafers with limitations.

A device for cleaning wafers is known from WO 2022/096657 A1 in which the cleaning fluid with which the inner surface of the FOUP has been cleaned can be removed from the device strictly separated from the cleaning fluid by which the outer surface of the FOUP has been cleaned. The fluid separation takes place at the marginal surface of the FOUP. It is, however, also desirable for the case that only the inner surface is cleaned to prevent the penetration of particles from the outer surface into the cleaning fluid during the cleaning of the inner surface and the uncontrolled exit of the cleaning fluid over the marginal surface.

As mentioned, the FOUPs are typically manufactured in an injection molding process. Due to the principle, the FOUPs can therefore only be produced with relatively large tolerances. As a result, the fluid separation or a sealing at the marginal surface is difficult.

### SUMMARY

It is the object of an embodiment of the present invention to provide a device for cleaning pot-shaped hollow bodies, in particular transport containers for semiconductor wafers or for lithography masks, by which it is possible with technically simple and inexpensive means to provide a remedy for the above-named disadvantages and in particular to reliably provide a seal or a fluid separation at the marginal surface independently of the tolerances of the FOUPs to be cleaned.

This object is achieved by the features specified in claim 1. Advantageous embodiments are the subject of the dependent claims.

An embodiment of the invention relates to a device for cleaning pot-shaped hollow bodies, in particular transport containers for semiconductor wafers or for lithography masks, wherein the hollow body comprises a base wall and one or more side walls that form an inner hollow body surface; and an opening that is disposed opposite the base wall and that is surrounded by a marginal surface of the side wall, wherein the device has a support wall on which the marginal surface of the hollow body can be placed; a cleaning device by which a first cleaning fluid for cleaning the inner hollow body surface can be dispensed when the hollow body is connected to the support wall; and a feed device that is arranged in the support wall or is fastened to the support wall and by which a flushing fluid can be guided to the marginal surface, with the feed device comprising a movable element that is movable toward the marginal surface by the flushing fluid. It is assumed in the following embodiments that the hollow body is connected to the support wall.

In particular nitrogen or compressed air, and particularly preferably extreme clean dried air, also called XCDA, is used as the flushing fluid. During the cleaning of the inner hollow body surface, the flushing fluid is conducted at a sufficiently high pressure into the feed device where the flushing fluid effects a movement of the movable element toward the marginal surface. The movable element can have a certain elasticity as a result of which the movable element can adapt to the extent of the marginal surface and at least approximately contacts the marginal surface without interruption. The elasticity here is greater than that of the marginal surface. In addition, expansion spaces can be provided into which the movable element can expand when it is moved toward the marginal surface and is deformed accordingly. As a result, a reliable seal is provided independently of the tolerances of the affected marginal surface. The seal prevents particles from being able to move from the outer hollow body surface into the first cleaning fluid during the cleaning of the inner hollow body surface. It is ensured that the particles removed with the first cleaning fluid exclusively originate from the inner hollow body surface. The number of removed particles can be counted. If the number falls below a certain value, the cleaning can be terminated since it is then ensured that the inner hollow body surface has been sufficiently cleaned. The seal additionally has the effect that the inner hollow body surface is not contaminated by particles of the outer hollow body surface or of the environment.

In accordance with a further embodiment, a recess in which the movable element is movably supported can be arranged in the support wall. The use of a recess structurally represents a simple possibility of guiding the movable element such that it is moved to the marginal surface on pressurization using the flushing fluid.

In a further developed embodiment, the movable element can have a sealing surface facing toward the marginal surface and a distributor channel and a plurality of dispensing channels starting from the distributor channel and leading to the sealing surface. It is possible to use the movable element as a purely sealing element that is sealingly pressed toward the marginal surface by means of the flushing fluid, with the movable element coming into contact with the marginal surface. It is, however, also possible to use the flushing fluid as a barrier medium for which purpose it is not necessary to establish any contact between the marginal surface and the movable element. In this case, a fluidic seal is provided. The flushing fluid is guided to the sealing surface by the dispensing channels. It is not necessary in this case that the sealing surface comes into contact with the marginal surface. A sealing gap is rather produced. The constant flow of the flushing fluid has the effect here that the first cleaning fluid cannot exit through the sealing gap. It is, however, also necessary in this case to guide the movable element as closely as possible to the marginal surface since the effect of the flushing fluid as a barrier medium can only be reliably established up to a certain distance between the sealing surface and the marginal surface. Distance differences between the sealing surface and the marginal surface due to production inaccuracies can be bridged within certain limits so that a reliable seal is produced.

In a further developed embodiment, the movable element can have a plurality of guide channels extending in the sealing surface to conduct the flushing fluid along the sealing surface. Depending on the design of the device, it may be sensible or even necessary to guide the flushing fluid in a certain direction. The flushing fluid can, for example, be conducted toward the first cleaning fluid to be led off with it. In an opposite viewpoint, it may also be desired to conduct the flushing fluid away from the first cleaning fluid. The flushing fluid can be conducted, as desired, by the extent of the guide channels along the marginal surface while forming a sealing gap.

In a further embodiment, the movable element can be fully or partially elastic, with the shape of the movable element being variable by the flushing fluid such that the movable element is movable toward the marginal surface. In this embodiment, the movable element can be formed in the manner of a hose that expands as a result of the pressurization by the flushing fluid and moves toward the marginal surface as a result of the shape change. The term “elastic” is to be understood accordingly within the framework of the present application. The required elasticity can in particular be provided by the selection of a suitable material, for example a rubber-like material. The elasticity of the movable element is greater than that of the marginal surface.

Due to the elastic design, the movable element can easily adapt to the extent of the marginal surface and can thus provide either a largely uninterrupted contact with the marginal surface or a uniform design of the sealing gap. To this extent, the term “movable element” can on the one hand, be understood within the framework of the present application such that the total element is moved toward the marginal surface and, on the other hand such that a movement of at least parts of the movable element toward the marginal region is produced as a result of a shape change.

A further developed embodiment can be characterized in that the device comprises at least a passage opening formed by the support wall; and a first drainage channel having a first end, wherein the first end of the first drainage channel is only in fluid communication with the passage opening and by which the first cleaning fluid dispensed by the cleaning device can be drained.

The passage opening inter alia serves the draining of the first cleaning fluid from the hollow body. The passage opening is arranged such that only the first cleaning fluid is drained through the passage opening, but not, for example, particles that originate from the outer hollow body surface. It is therefore ensured that only particles that originate from the inner hollow body surface are contained in the first drainage channel. The number of particles in the first cleaning fluid that flows through the drainage channel can be determined. As soon as the number has fallen below a certain value, the cleaning of the inner hollow body surface can be terminated. The consumption of the first cleaning fluid can be limited to the required amount. The time duration of the cleaning can additionally be reduced to the required degree.

In accordance with a further embodiment, the device can comprise a locking device by which the marginal surface of the hollow body can be releasably connected to the support wall. The hollow body can be positioned relative to the support wall by means of the locking device. A slipping of the hollow body during the cleaning and in particular during the pressurization of the movable element by the flushing fluid can be prevented.

It may be suitable in a further embodiment that the passage opening is arranged radially within the locking device on the support wall. The locking device is arranged on the support wall in this embodiment and thus in the vicinity of the marginal surface. Alternatively, the locking device could, for example, engage at the base wall of the hollow body. However, the base wall and the side walls would then be correspondingly loaded. In comparison with this, the loads of the base wall and of the side walls can be kept small in this embodiment even though the marginal surface is pressed toward the support wall with a comparatively high force by the locking device. A slipping of the hollow body can correspondingly also be prevented on high pressures of the flushing fluid.

In a further embodiment in which the base wall and the side wall form an outer hollow body surface, it may be suitable that the cleaning device has a second cleaning head by which a second cleaning fluid for cleaning the outer hollow body surface can be dispensed; and the device has a second drainage channel by which the second cleaning fluid dispensed from the second cleaning head can be drained.

In this respect, the device has a second drainage channel by which the second cleaning fluid dispensed from the second cleaning head can be drained. As initially mentioned, it is not absolutely necessary to also clean the outer hollow body surface. It can nevertheless be desired to keep the particle concentration in the clean rooms small, for example. In this embodiment, a cleaning of the outer hollow body surface is possible, with the second cleaning fluid being drained separately from the first cleaning fluid. A mixing of the first cleaning fluid and of the second cleaning fluid and an increase in the particle concentration in the first cleaning fluid resulting therefrom by the particles originating from the outer hollow body surface is prevented. It is consequently also prevented in the event that both the inner hollow body surface and the outer hollow body outer hollow body surface are cleaned that particles that originate from the outer hollow body surface can move onto the inner hollow body surface. The cleaning process of the inner hollow body surface is consequently not negatively influenced by the particles that originate from the outer hollow body surface. The already mentioned measurement of the number of particles in the first cleaning fluid can also be carried out on the use of the second cleaning fluid without the measurement of particles being falsified that originate from the outer hollow body surface. The number of particles in the second cleaning fluid can correspondingly be determined, likewise with the aim of ending the cleaning of the outer hollow body surface when the number has fallen below a specific value.

### BRIEF DESCRIPTION OF THE DRAWINGS

The accompanying figures, in which like reference numerals refer to identical or functionally-similar elements throughout the separate views and which are incorporated in and form a part of the specification, further illustrate the embodiments and, together with the detailed description, serve to explain the embodiments disclosed herein. It is to be noted, however, that the appended drawings illustrate only typical embodiments of this invention and are, therefore, not to be considered limiting of its scope, for the invention may admit to other equally effective embodiments. It is also emphasized that the figures are not necessarily to scale and certain features and certain views of the figures can be shown exaggerated in scale or in schematic for clarity and/or conciseness.

FIG. 1A depicts a basic sectional representation through an embodiment of a device for cleaning pot-shaped hollow bodies, in particular transport containers for semiconductor wafers or for lithography masks.

FIG. 1B depicts an enlarged representation, not to scale, of the detail A defined in FIG. 1A with a movable element in accordance with a first embodiment.

FIG. 1C depicts an enlarged representation, not to scale, of the movable element shown in FIG. 1B.

FIG. 2 depicts an enlarged representation, not to scale, of the detail A defined in FIG. 1A with a movable element in accordance with a second embodiment.

### DETAILED DESCRIPTION

A more detailed description of the invention provided herein will now be provided. The present invention will be described in connection with numerous embodiments. Such discussion is for purposes of illustration only and not intended to be limitative of the invention. Modifications to particular embodiments within the spirit and scope of the present invention, set forth in the appended claims, will be readily apparent to those of skill in the art. Accordingly, it is to be understood that the following disclosure describes several exemplary embodiments for implementing different features, structures, or functions of the invention. Exemplary embodiments of components, arrangements, and configurations are described below to simplify the present disclosure; however, these exemplary embodiments are provided merely as examples and are not intended to limit the scope of the invention.

The scope of the invention is defined in the appended claims, which for infringement purposes is recognized as including equivalents to the various elements or limitations specified in the claims. Depending on the context, all references to the “invention” may in some cases refer to certain specific embodiments only. In other cases, it will be recognized that references to the “invention” will refer to subject matter recited in one or more, but not necessarily all, of the claims. Each of the inventions will now be described in greater detail below, including specific embodiments, versions and examples, but the inventions are not limited to these embodiments, versions or examples, which are included to enable a person having ordinary skill in the art to make and use the inventions, when the information in this disclosure is combined with publicly available information and technology.

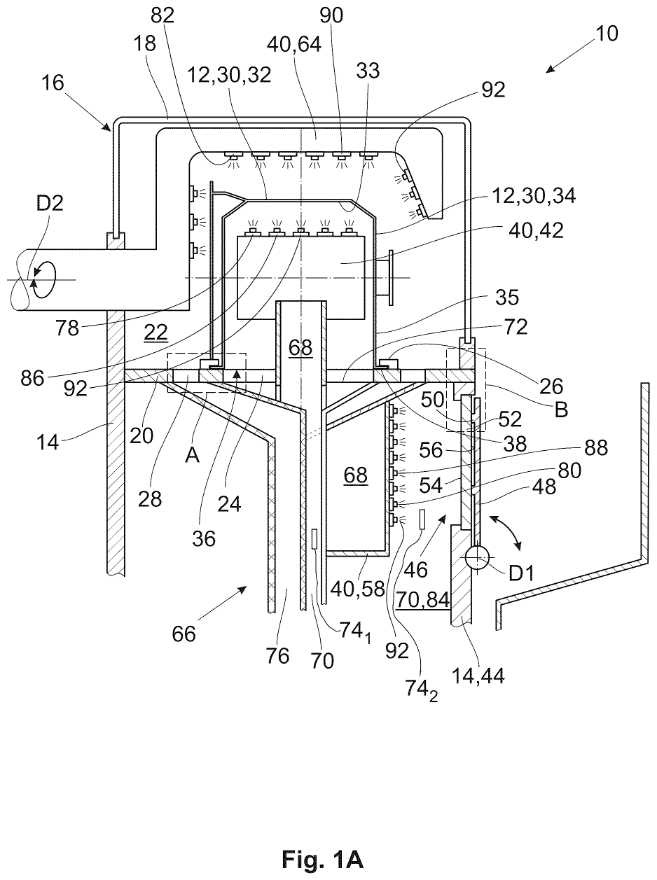

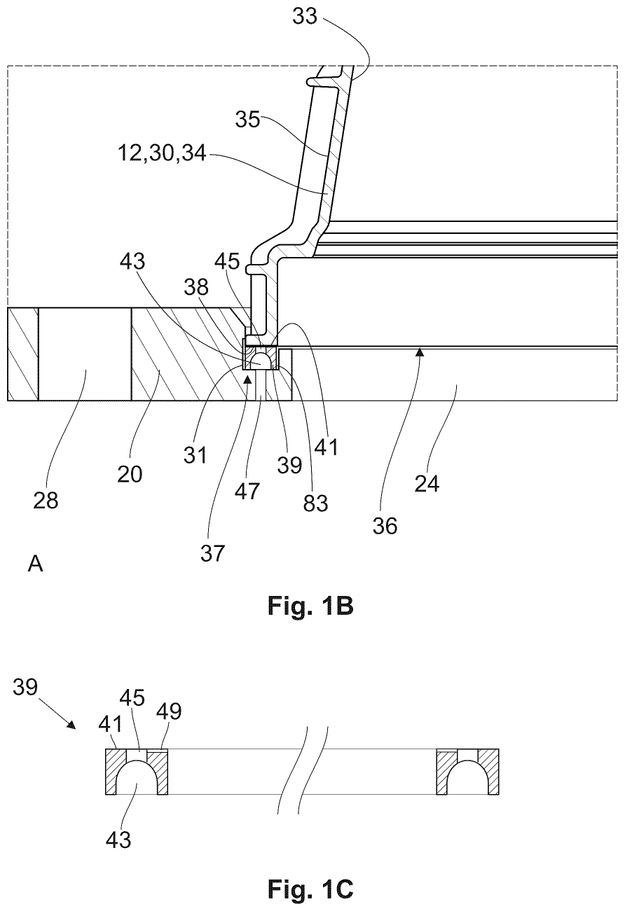

Referring to the figures, an embodiment of a device 10 in accordance with the proposal for cleaning pot-shaped hollow bodies 12 is shown with reference to a basic sectional representation in FIG. 1A. The device 10 has a housing 14 that forms a housing opening 16 that is closable by a cover 18 removable from the housing 14. A support wall 20 is furthermore arranged in the housing 14 so that a closed process space 22 is provided in the housing 14. The process space 22 is bounded by the support wall 20, by the housing 14 itself, and by the cover 18. The support wall 20 forms a passage opening 24, with a locking device 26 being arranged radially outside the passage opening 24. Two passage bores 28 are provided in the support wall 20 radially outside the locking device 26 in the embodiment shown.

With a removed cover 18, a hollow body 12, in particular a transport container 30 for semiconductor wafers, also called an FOUP, or a transport container 30 for lithium masks, can be introduced into the process space 22. The hollow body 12 has a base wall 32 and, in this case, four side walls 34 so that the pot-shaped hollow body 12 is substantially parallelepiped-shaped. It is, however, by all means possible to provide the pot-shaped hollow body 12 with a different geometry, for example a cylindrical geometry. The base wall 32 and the four side walls 34 form an inner hollow body surface 33 and an outer hollow body surface 35.

The hollow body 12 has an opening 36 that is arranged disposed opposite the base wall 32 and that is surrounded by a marginal surface 38 that is formed by the side walls. The hollow body 12 is designed in the manner of a flange in the region of the marginal surface 38 in the embodiment shown. The marginal surface 38 of the hollow body 12 can be placed onto the support wall 20. The passage opening 24 of the support wall 20 and the opening 36 of the hollow body 12 are at least approximately the same size and the same geometrical shape in the embodiment shown.

The locking device 26 is furthermore configured such that the passage opening 24 is at least approximately flush with the section of the inner hollow body surface 33 adjoining the passage opening 24.

The region A marked in FIG. 1A is not shown enlarged to scale in FIG. 1B, with no exact agreement being present. For illustration reasons, the locking device 26 is not shown. It can be recognized from FIG. 1B that the support wall 20 comprises a recess 31 in which a feed device 37 is arranged by which a flushing fluid, for example air or nitrogen, can be conducted to the marginal surface 38. The feed device comprises a movable element 39 in accordance with a first embodiment that is movably supported in the recess 31. The movable element 39 is provided with a sealing surface 41 facing toward the marginal surface 38. The movable element 39 additionally has a distributor channel 43 and a plurality of dispensing channels 45 originating from the distributor channel 43 and extending toward the sealing surface 41. A supply channel 47 through which the flushing fluid can be conveyed into the distributor channel 43 is furthermore arranged in the support wall 20.

The movable element 39 shown in FIG. 1B is shown enlarged and isolated in FIG. 1C, with the same sectional plane having been used as in FIGS. 1A and 1B. It can be recognized that a plurality of guide channels 49 extend on the sealing surface 41.

With reference to FIG. 1A, the device 10 is equipped with a cleaning device 40 that has a first cleaning head 42, that projects over the passage opening 24 and is thus arranged within the process space 22. When the hollow body 12 is connected to the support wall 20, the first cleaning head 42 is surrounded by the hollow body 12.

The housing 14 further comprises a wall section 44 in which a cleaning opening 46 is arranged. The wall section 44 is located at the side of the side wall 20 remote from the locking device 26. The cleaning opening 46 is at least partially closable by a closure body 48 that is rotatably fastened to the wall section 44 about a first axis of rotation D1 by a drive unit, not shown. The closure body 48 can be moved between an open position in which the closure body 48 releases the cleaning opening 46 and a closure position in which the closure body 48 at least partially closes the cleaning opening 46. The closure body 48 is in the closure position in FIG. 1A.

The closure body 48 has a reception nit 50 by which a cover 52 by which the hollow body 12 is closable can be releasably fastened to the closure body 48. The cover 52 forms an inner cover surface 54 and an outer cover surface 56. The inner cover surface 54 is here that side of the cover 52 that directly adjoins the inner hollow body surface 33 when the hollow body 12 has been closed by the cover 52. In other words, the inner cover surface 54 in this case faces toward the base wall 32 of the hollow body 12.

The reception unit 50 is designed in the embodiment shown such that it only interacts with the cover 52 by means of the outer cover surface 56.

The cleaning device 40 is additionally equipped with a further first cleaning head 58 that is arranged in the vicinity of the closure body 48 when it is in the closure position.

The cleaning device 40 moreover comprises a second cleaning head 64 that is substantially formed in U shape and is at least partially arranged in the process space 22. Unlike the first cleaning head 42, however, the second cleaning head 64 is arranged outside the hollow body 12 when the hollow body 12 is connected to the support wall 20 as shown in FIG. 1A. The second cleaning head 64 is rotatable about a second rotational axis D2, with the drive device used for this purpose not being shown. An embodiment is furthermore not shown in which the second cleaning head 64 is not only movable rotationally, but also translationally or only translationally. In the embodiment shown, the first cleaning head 42 is not movable; however, it can also be designed as rotationally and/or translationally movable.

The device 10 is furthermore provided with a fluid conducting unit 66 by which a first cleaning fluid can be conducted to the first cleaning head 42 and to the further first cleaning head 58 and a second cleaning fluid can be conducted to the second cleaning head 64. The fluid conducting element 66 has a first feed channel 68 by which the first cleaning fluid can be conducted to the first cleaning head 42.

A detailed representation of a second feed channel for feeding the second cleaning fluid to the second cleaning head 64 has been dispensed with for illustration reasons, but its design should be easily deducible for the skilled person.

The fluid conducting unit 66 furthermore comprises a first drainage channel 70 by which the first cleaning fluid dispensed by the first cleaning head 42 and by the further first cleaning head 58 can be drained from the process space 22 again. The first drainage channel 70 has a first end 72 that is in fluid communication with the passage opening 24. As can be seen from FIG. 1A, the first drainage channel 70 is expanded in funnel shape toward the first end 72 and is connected to the support wall 20 such that the first end 72 of the drainage channel terminates flush with the passage opening 24.

A first particle measuring device 74₁ is arranged in the first drainage channel 70 by which the particles that are in the first cleaning fluid and that originate from the inner hollow body surface 33 can be determined and in particular counted. A second particle measuring device 74₂ is additionally arranged in the second drainage channel 74₂ by which the particles that are in the first cleaning fluid and that originate from the inner cover surface 54 can be determined and in particular counted.

The fluid conducting unit 66 furthermore has a second drainage channel 76 that is designed substantially exactly the same as the first drainage channel 70, but is in fluid communication with the two passage bores 28. In this respect, the first drainage channel 70 forms the radial inner wall of the second drainage channel 76 so that the fluid conducting unit 66 can have a very compact design. An embodiment is not shown in which a further particle measuring device 74 is arranged in the second drainage channel 76. It must be pointed out at this point that the fluid conducting unit 66 is only shown in principle in FIG. 1A. The representation of the fluid conducting unit 66 in accordance with FIG. 1A does not make any claims of correctness due to the large number of channels arranged nested and at different levels. The skilled person will, however, be able to at least deduce a functional design of the fluid conducting unit 66 without problem from FIG. 1A.

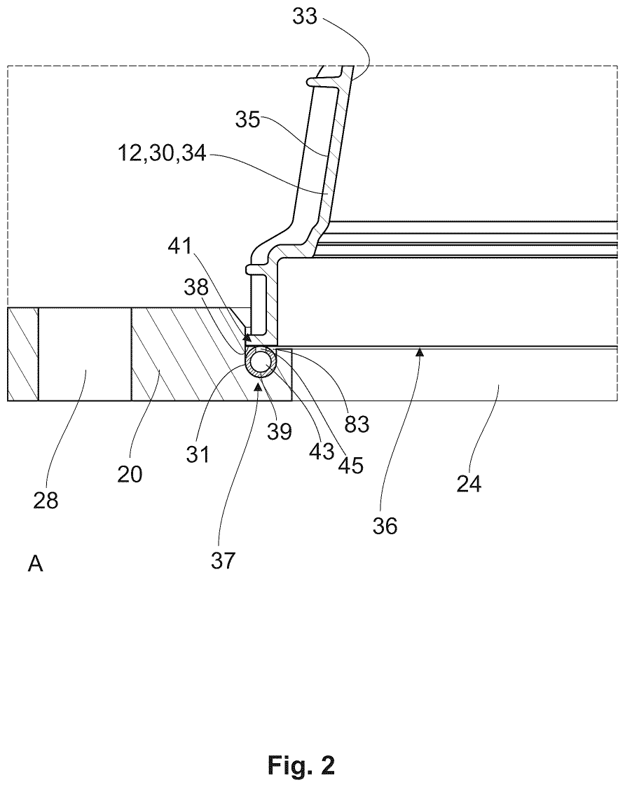

The feed device 37 is shown again in FIG. 2 that has a movable element 39 in accordance with a second embodiment. In the second embodiment, the movable element 39 is elastic so that the movable element 39 expands when the flushing fluid is introduced into the distributor channel 43 at a sufficient pressure. As can be recognized from FIG. 2, the movable element 39 is of hose form, with the recess 31 being shaped in the region of its base complementary to the hose-like movable element 39. With respect to the sectional plane, the base of the recess 31 is formed in semicircular shape. When the flushing fluid is introduced into the distributor channel 43, the movable element 39 can only expand toward the marginal surface 38 due to the design of the recess 31 and is moved to there as a result.

The device 10 is operated in the following manner: In the starting state, not shown here, the cover 18 is open and the second cleaning head 64 is rotated by 90° with respect to FIG. 1A so that the U-shaped section of the second cleaning head 64 is perpendicular to the plane of FIG. 1A. The closure body 48 is in the open position in which the closure body 48 is aligned approximately horizontally with respect to FIG. 1A.

The cover 52 is separated from the hollow body 12 and placed onto the reception unit 50 by a handling device, not shown, for example by a gripping robot. The open hollow body 12 is introduced into the process space 22 such that the marginal surface 38 of the hollow body 12 lies on the support wall, as is shown in FIG. 1A. The hollow body 12 is subsequently locked by the locking unit 26 so that it is connected to the support wall 20 and is thus fixed in the process space 22. In this respect, the locking device 26 is equipped with sealing agents, not shown here, so that the hollow body 12 is sealed with respect to the support wall 20. The cover 18 is now closed. In addition, the reception unit 50 of the closure body 48 is activated so that the cover 52 is fixed at the closure body 48. The closure body 47 is rotated by 90° into the closure position, as is shown in FIG. 1A. The cover 52 here seals the cleaning opening 46.

A first cleaning fluid is now conducted over the first feed channel 68 to the first cleaning head 42 and is dispensed through first cleaning nozzles 78 such that the inner hollow body surface 33 is cleaned by the first cleaning fluid. The further first cleaning head 58 has further first cleaning nozzles 80 by which the first cleaning fluid is applied to the inner cover surface 54 that is consequently cleaned.

At the same time, a second cleaning fluid that can correspond to the first cleaning fluid is conducted over the second feed channel, not shown here, to the second cleaning head 64 where the second cleaning fluid is dispensed by second cleaning nozzles 82 to clean the outer hollow body surface 35. In this respect, the second cleaning head 64 can be rotated about the second rotational axis D2.

The first cleaning nozzles 78, the further first cleaning nozzles 80, and the second cleaning nozzles 82 can be configured such that the spray angle α at which the first cleaning fluid and the second cleaning fluid are dispensed is settable. For this purpose, the first cleaning nozzles 78, the further first cleaning nozzles 80, and the second cleaning nozzles 82 can be supported in spherical head shape.

At the same time, the flushing fluid is guided toward the marginal surface 38 while using the feed device 37. In this respect, the flushing fluid is conveyed into the supply channel 47 by a pump in a manner not shown in any more detail (see FIG. 1B), with the flushing fluid being at a sufficiently high pressure here. The flushing fluid moves from the supply channel 47 into the distributor channel 43 and from there into the dispensing channels 45. When leaving the dispensing channels 45, the large part of the flushing fluid impacts the marginal surface 38. A portion of the flushing fluid flows through the guide channels 49 toward the passage opening 24. A flow of the total flushing fluid toward the passage opening 24 is hereby induced. As a result, the flushing fluid flows into the first cleaning fluid while forming a sealing gap between the sealing surface 41 and the marginal surface 38.

Due to the back pressure that forms, in accordance with the first embodiment the movable element 39 is raised and moved toward the marginal surface 38. In the second embodiment, the movable element 39 is expanded and as a result moves toward the marginal surface 38. In both cases, a uniform sealing gap also forms when the marginal surface 38 has irregularities due to tolerances.

Expansion spaces 83 are provided to enable the movement and/or the deformation or expansion of the movable element 39. With respect to FIG. 1B, the expansion spaces 83 are formed in the first embodiment by an annular gap between the movable element 39 and the recess 31. The annular gap is dimensioned such that, on the one hand, a movement of the movable element 39 toward the marginal surface 38 is made possible; on the other hand, a certain guidance is effected that prevents a canting of the movable element 39 in the recess 31.

As mentioned, the base of the recess 31 in the second embodiment is semicircular while the movable element 39 is circular. The expansion spaces 82 are formed between he movable element 39 and the marginal surface 38.

The flushing fluid provides that neither the first cleaning fluid nor the second cleaning fluid can cross over the marginal surface 38. The flushing fluid therefore effects a fluidic seal between the first cleaning fluid and the second cleaning fluid. It is consequently ensured that the first cleaning fluid and the second cleaning fluid cannot mix. A contamination of the first cleaning fluid with the second cleaning fluid and vice versa is prevented.

The first cleaning fluid that has been dispensed by the first cleaning head 42 and that has been applied to the inner hollow body surface 33 is drained by the first drainage channel 70. The same also applies to the first cleaning fluid that has been dispensed by the further first cleaning head 58 and that has been applied to the inner cover surface 54. The flushing fluid is also drained through the first drainage channel with the first cleaning fluid. The first drainage channel 70 has a secondary channel 84 that opens into the first drainage channel 70 to drain the first cleaning fluid that is used to clean the inner cover surface 54.

Particles that were located on the inner hollow body surface 33 and on the inner cover surface 54 are removed by the first cleaning fluid. The particles that originate from the inner hollow body surface 33 are detected by the first particle measuring device 74₁ and the particles that originate from the inner cover surface 54 are detected by the second particle measuring device. In this respect, the first particle measuring device 74₁ and the second particle measuring device 74₂ are configured such that the number of particles that pass through the particle measuring device 74 on a given volume flow within a certain time is determined. It can hereby be determined whether the inner hollow body surface 33 and the inner cover surface 54 have been cleaned to the desired degree or not. If, for example, the inner hollow body surface 33 is sufficiently clean, the cleaning process for the hollow body 12 can be aborted while the cleaning process for the inner cover surface 54 is continued. In the meantime, the hollow body 12 can be removed from the device by the robot gripper, whereby time can be saved.

As mentioned, a further particle measuring device 74 can be arranged in the second drainage channel 76. The particles that originate from the outer hollow body surface 35 can be detected by this further particle measuring device. This information can also be integrated in the decision whether the cleaning process for the hollow body 12 can be aborted or not. If the charge of the first cleaning fluid with particles originating from the inner hollow body surface 33 does not exceed a specific value, it can also be used for the cleaning of the outer hollow body surface 35.

An embodiment is not shown in which the particle measuring device 74 is arranged downstream of the opening of the secondary channel 84 into the first drainage channel 70. In this case, no distinction can be made whether the particles have originated from the inner cover surface 54 or from the inner hollow body surface 33. The cleaning process can nevertheless be aborted when the number of particles falls below a certain degree.

The second cleaning fluid that has been dispensed by the second cleaning head 64 and that has been applied to the outer hollow body surface 35 is drained over the second drainage channel 76. Consequently, the first cleaning fluid and the second cleaning fluid are drained separately from one another as a result of which particles that originate from the outer hollow body surface 35 cannot enter into the first cleaning fluid and thus not onto the inner hollow body surface 33 or onto the inner cover surface 54.

The cleaning of the inner hollow body surface 33 and of the inner cover surface 54 generally has a greater importance than the cleaning of the outer hollow body surface 35. If it is found that the inner hollow body surface 33 and the inner cover surface 54 have been cleaned to the desired degree, the cleaning process can be aborted independently of the degree to which the outer hollow body surface 35 has been prepared.

A first drying gas and a second drying gas, for example air or nitrogen, can now be conducted over the first feed channel 68 or over the second feed channel in largely the same manner as the first and second cleaning fluids to the first cleaning head 42, to the further first cleaning head 58, and to the second cleaning head 64. The first cleaning head 42 has first drying nozzles 86, the further first cleaning head 84 has further first drying nozzles 88, and the second cleaning head has second drying nozzles 90 by which the first drying gas or the second drying gas can be dispensed and applied to the inner hollow body surface 33, to the inner cover surface 54, and to the outer hollow body surface 35. The first drying gas and the second drying gas displace the first cleaning fluid and the second cleaning fluid from the device 10. Residues of the first and second cleaning fluids can moreover be blown away.

The first cleaning head 42, the further first cleaning head 58, and the second cleaning head furthermore have infrared diodes 92 by which residues of the first and second cleaning fluids can be heated and vaporized, as a result of which they can be removed from the device 10 by the first and second drying gases.

After the termination of the drying process, the cover 18 is opened and the closure body 48 is moved into the open position. The cleaned hollow body 12 is removed from the process space. The reception unit 50 is deactivated, as a result, the cover 52 can be removed from the closure body 48 and fed to the hollow body 12 for the closing thereof. A further hollow body 12 to be cleaned can now be treated in the described manner in the device 10.

### REFERENCE NUMERAL LIST

10 device
12 hollow body
14 housing
16 housing opening
18 cover
20 support wall
22 process space
24 passage opening
26 locking device
28 passage bore
30 transport container
31 recess
32 base wall
33 inner hollow body surface
34 side wall
35 outer hollow body surface
36 opening
37 feed device
38 marginal surface
39 movable element
40 cleaning device
41 sealing surface
42 first cleaning head
43 distributor channel
44 wall section
45 dispensing channel
46 cleaning opening
47 supply channel
48 closure body
49 guide channel
50 reception unit
52 cover
54 inner cover surface
56 outer cover surface
58 further first cleaning head
64 second cleaning head
66 fluid conducting unit
68 first feed channel
70 first drainage channel
72 first end
74 particle measuring device
76 second drainage channel
78 first cleaning nozzle
80 further first cleaning nozzles
82 second cleaning nozzles
83 expansion space
84 secondary channel
86 first drying nozzles
88 further first drying nozzles
90 second drying nozzles
92 infrared diodes
D1 first rotational axis
D2 second rotational axis

The foregoing has outlined features of several embodiments so that those skilled in the art can better understand the present disclosure. Those skilled in the art should appreciate that they can readily use the present disclosure as a basis for designing or modifying other methods or devices for carrying out the same purposes and/or achieving the same advantages of the embodiments disclosed herein. Those skilled in the art should also realize that such equivalent constructions do not depart from the spirit and scope of the present disclosure, and that they can make various changes, substitutions, and alterations herein without departing from the spirit and scope of the present disclosure, and the scope thereof is determined by the claims that follow.

To the extent a term used in a claim is not defined above, it should be given the broadest definition persons in the pertinent art have given that term as reflected in at least one printed publication or issued patent. Furthermore, all patents, test procedures, and other documents cited in this application are fully incorporated by reference to the extent such disclosure is not inconsistent with this application and for all jurisdictions in which such incorporation is permitted.

What is claimed is:

1. A device for cleaning pot-shaped hollow bodies, in particular transport containers for semiconductor wafers or for lithography masks, comprising:
a hollow body that comprises a base wall and one or more side walls that form an inner hollow body surface; and an opening that is disposed opposite the base wall and that is surrounded by a marginal surface of the side wall,
a support wall on which the marginal surface of the hollow body can be placed;
a cleaning device by which a first cleaning fluid for cleaning the inner hollow body surface can be dispensed when the hollow body is connected to the support wall; and
a feed device that is arranged in the support wall or is fastened to the support wall and by which a flushing fluid can be guided to the marginal surface, with the feed device comprising a movable element that is movable toward the marginal surface by the flushing fluid.

2. The device of claim 1, further comprising a recess in which the movable element is movably supported is arranged in the support wall.

3. The device of claim 1, wherein the movable element has a sealing surface facing toward the marginal surface; and a distributor channel having a plurality of dispensing channels starting from the distributor channel and leading to the sealing surface.

4. The device of claim 3, wherein the movable element has a plurality of guide channels extending in the sealing surface to conduct the flushing fluid along the sealing surface.

5. The device of claim 1, wherein the movable element is fully or partially elastic, with the shape of the movable element being variable by the flushing fluid such that the movable element is movable toward the marginal surface.

6. The device of claim 1, further comprising at least one passage opening formed by the support wall and a first drainage channel having a first end, wherein the first end of the first drainage channel is only in fluid communication with the passage opening and by which the first cleaning fluid dispensed by the cleaning device can be drained.

7. The device of claim 1, further comprising a locking device by which the marginal surface of the hollow body can be releasably connected to the support wall.

8. The device of claim 7, wherein the passage opening is arranged radially within the locking device on the support wall.

9. The device of claim 7, wherein the base wall and the side wall form an outer hollow body surface, wherein the cleaning device has a second cleaning head unit by which a second cleaning fluid for cleaning the outer hollow body surface can be dispensed; and the device has a second drainage channel by which the second cleaning fluid dispensed by the second cleaning head can be drained.
